(19) United States
(12) Patent Application Publication
(10) Pub. No.: US 2004/0237013 A1
(43) Pub. Date: Nov. 25, 2004

(54) Apparatus and method for sensing emulator cable orientation while providing signal drive capability

(76) Inventors: Lee A. Larson, Katy, TX (US); Ronald L. Lerner, Houston, TX (US)

Correspondence Address: TEXAS INSTRUMENTS INCORPORATED, P O BOX 655474, M/S 3999, DALLAS, TX, 75265

(21) Appl. No.: 10/851,842

(22) Filed: May 21, 2004

Related U.S. Application Data
(60) Provisional application No. 60/473,275, filed on May 23, 2003.

(51) Int. Cl. H01R 4/24; H01R 4/26; H01R 11/00; G01R 31/28; H01R 11/20

(52) U.S. Cl. 714/724

(57) ABSTRACT

In a cable electrically coupling a target processor and an emulator/test unit, two sense lines are selected that have corresponding terminals on the connects that are symmetrical under 180° rotation of the connectors. Characteristics of at least one sense line are determined. Based on the characteristics of at least one of the sense lines, the relative orientation of the sense lines can be determined. With this determination, the terminals to which the sense lines are coupled in the target processor can be determined. Signals can be applied to and/or received from at least one sense line. In the preferred embodiment, the sense line coupled to the /TRST JTAG terminal of the target processor can be identified. The characteristics of at least one sense line can determine the signals associate with each cable conductor.

This application claims priority under 35 USC §119(e) (1) of Provisional Application Serial No. 60,473,275 (TI-35197 P), filed May 23, 2003.

### 1. FIELD OF THE INVENTION

This invention relates generally to the testing of digital signal processing units and, more particularly, to the apparatus facilitating exchange of data between digital signal processing unit under test and the unit receiving the test signals.

### 2. BACKGROUND OF THE INVENTION

In order to test digital signal processor-based systems, an emulator unit is typically employed. Referring to FIG. 1, a test and debug configuration for testing a target processor 11 using an emulator unit 12 is shown. The target processor 11 is coupled to emulation unit 12 by cable 15. The test and debug of the target processor 11 is performed under the control of a host processing unit (not shown) that controls the operation of the emulation unit. The host processing unit generates the test and debug commands and analyzes data from the target processor 11. The emulation unit 12 acts as an interface between the target processor 11 and the host processing unit. The emulation unit 12 will reformat commands from the host processing unit into a format executable by the target processor 11, while data from the target processor 11 is reformatted into a form that can be processed by the host processing unit. In some embodiments, the emulation unit 12 can be integrated with the host processing unit and included on the same circuit board as the host processing unit.

An emulator cable 15, according to the prior art, is shown in FIG. 2. The emulator cable 15 includes a conductor cable 25, a female connector 21, and a male connector 22, although in some applications, the connectors may be the same gender. The conductors of the conductor cable 25 couple each female connector element 211 to a corresponding male connector element 221. In addition, each female connector 21 and each male connector 22 are symmetric under 180° rotation. In particular, two selected connector elements, 211A and 211B, of the female connector 21 and two corresponding connector elements, 221A and 221B, of the male connector 22 are selected such that, with a 180° rotation of the two conductors, the two connector elements change position. The connector elements 211A, 211B, 212A, 212B, and the conductors coupling these connector elements are referred to as the sense lines.

Current JTAG (Joint Test Action Group) emulation connectors, with a typically 14 pin connector element, use a key pin to insure the cable is installed correctly. While effective, it means the key pin cannot be used for any other function. Advanced emulation functions such as trace and high speed RTDX protocols require emulation connectors with more signal pins and more ground connections to support the higher signaling rates. Because of the desire for more signal pins and the desire to reduce the footprint of the connector on the user's board, a means of sensing connector element orientation and still providing signal capability is required. The next generation emulation cables may have 2 conducting paths. This emulator cable may not include a keying function so that the user can accidentally install a connector element rotated by 180°. A technique must be provided so that relative rotation of the connector elements is identified and the user is notified without damage to either the target processor 11 or to emulation unit 12.

It is known in the prior art to provide two conductor terminals, symmetrically located with respect to a 180° rotation of the cable connector, are used to detect the orientation of the emulation unit cable connector relative to the target processor cable connector. Connector elements 211A and 221A are labeled sense 1 connectors and connector elements 211B and 221B are designated as sense 2 connectors as illustrated in FIG. 2. In the emulation unit 12, one of the terminals to which sense 1 and sense 2 elements can be coupled is grounded. The target processor determines which sense connector is grounded and can thereby determine the relative orientation of the connectors 21 and 22. Once the relative orientation of the connectors is determined, the identification of the transmitted signals can be determined.

Because of the large amount of data that is exchanged between the target processor and the emulation unit, it would be desirable to select any combination of sense lines that permit the identification of the relative orientation of the connectors of an emulation cable as well as exchange signals over at least one of the sense lines. It would also be desirable to be able to exchange signals over any of the sense lines. It would be further desirable to characterize the sense lines in a controlled manner. It would also be desirable to characterize the sense lines in terms of impedance and/or voltage. In addition for the JTAG format testing, it would be desirable to identify a terminal in the target processor is typically designated to receive the /TRST signal.

A need has therefore been felt for apparatus and an associated method that would provide a characterization of the sense lines forming the signal paths coupling a target processor and test apparatus. It would be a further feature of the apparatus and associated method to characterize individually the sense lines forming part of the electrical coupling of a test apparatus and a target processor. It would be a still further feature of the apparatus and associated method to provide for transmission of data over at least one of the sense lines. It would be yet a further feature of the apparatus and associated method to specify to which pins in the target processor the sense lines are coupled. It would be a more particular feature of the present invention to be able to identify a particular sense line as receiving a /TRST JTAG signal.

### SUMMARY OF THE INVENTION

The aforementioned and other features are accomplished, according to the present invention, by selecting any combination of sense lines symmetrical under 180° relative rotation of the cable connectors of an emulator cable. Test apparatus can select a first sense line and provide a characterization of the sense line. The test apparatus may then select a second sense line and characterize the second sense line. The characterization determines the availability of the sense line for exchange of data. In response to control signals generated as a result of the characterization, pre-identified terminals can be coupled to a sense line based on the characterization. In particular, the test apparatus can determine the JTAG /TRST terminal.

Other features and advantages of present invention will be more clearly understood upon reading of the following description and the accompanying drawings and the claims.

### BRIEF DESCRIPTION OF THE DRAWINGS

FIG. 1 is a block diagram of the components of a test and debug unit according to the prior art.

FIG. 2 is a perspective view of an emulator cable according to the prior art.

FIG. 3 is a block diagram illustrating the apparatus for determining the relative orientation of emulation cable connectors using two sense lines and the characteristics of the terminals to which terminals are coupled according to the present invention.

FIG. 4 is a block diagram illustrating a first implementation for sensing the relative orientation of emulator cable connectors and determination of the characteristics of the terminals coupled to the sense lines according to the present invention.

FIG. 5 is a block diagram illustrating a second implementation for sensing the relative orientation of emulator cable connectors and the characteristics of the sense lines coupled thereto according to the present invention.

### DESCRIPTION OF THE PREFERRED EMBODIMENT

1. Detailed Description of the Figures

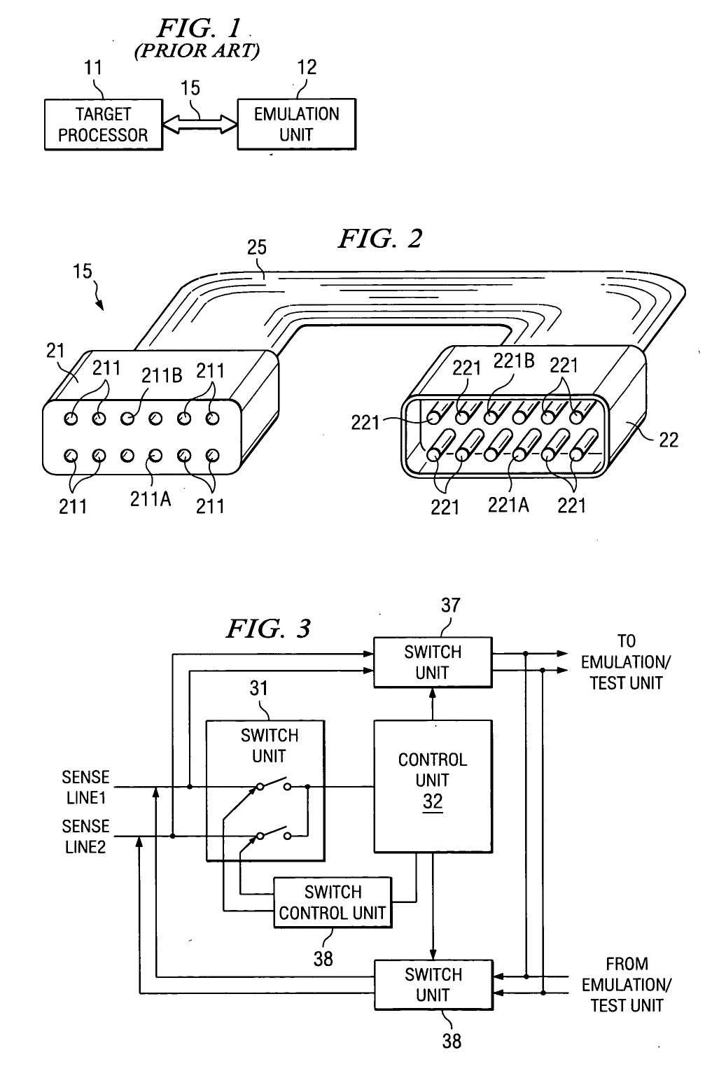

FIG. 1 and FIG. 2 have been described with respect to the related art.

Referring now to FIG. 3, a block diagram of the apparatus for determining the characteristics of two sense lines. As indicated above, the two conductor sense lines, SENSE 1 and SENSE 2, are symmetrical with respect to 180° rotation of the cable connectors. The sense lines are applied to the two input terminals of analog switch 31. The analog switch 31 permits signals to be transmitted in both directions when a switch element is closed. The decision logic unit 32 applies signals to switch control unit 34. The switch control unit 34 closes a selected one of the switches in the switch unit 31 thereby coupling a selected sense line to the decision logic unit 32. The decision logic unit 32 determines characteristics of the selected sense line. After the characteristics of the selected sense line have been determined, then the decision logic unit 32 provides signal to the switch control unit 34. These signals select and couple the second sense line decision logic unit after decoupling the originally selected sense line from decision logic unit 34. The characteristics of the second sense line are determined by the decision logic unit 34. Based on the characteristics of the two sense lines, the signals applied to the sense lines and the signals received from the sense lines can be directed in an appropriate manner to the emulator/test unit. The decision logic unit 32 applies ENABLE signals to switch units 37 and 38. Switch unit 37 determines to which apparatus the signals from the sense lines are directed, while switch unit 38 determines to which of the sense lines the signals from the emulation/test unit are directed. In particular, the /TRST JTAG signal can be directed to the appropriate sense line.

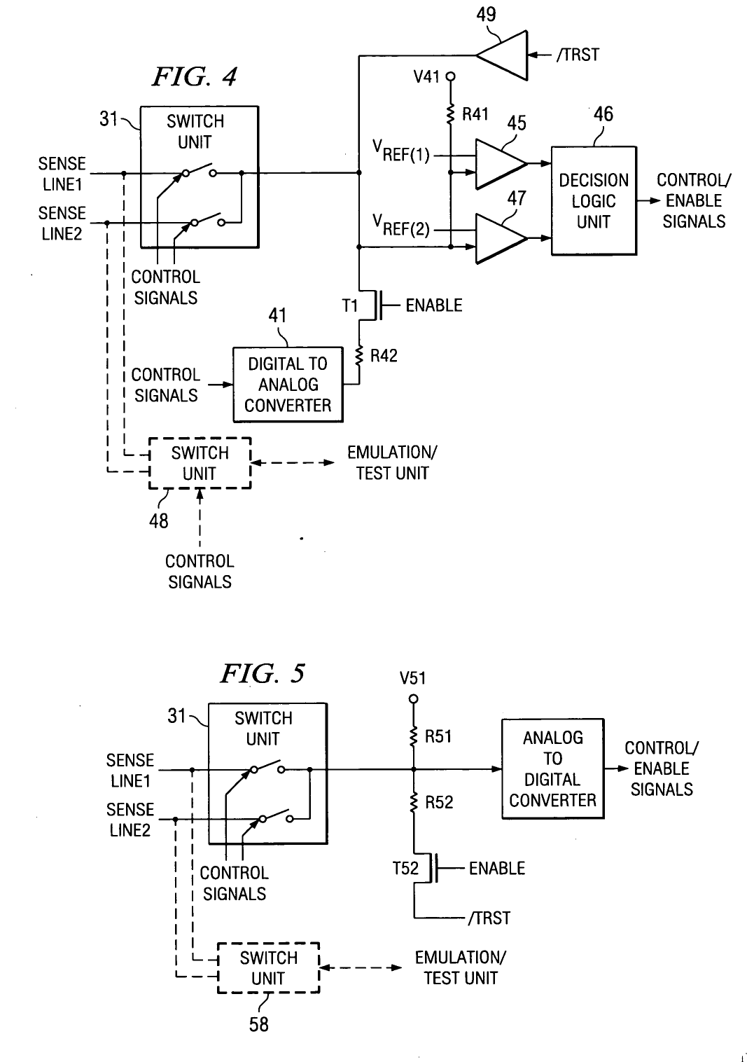

FIG. 4 and FIG. 5 illustrate different configuration for determining the characteristics of the sense line (terminations). Referring to FIG. 4, a determination is made whether a sense line is terminated with a high or a low impedance. In response to control signals, one of the sense lines is coupled to an output terminal of switch unit 31. The output terminal of switch unit 31 is coupled through resistor R41 to voltage source V41, is coupled through the serially coupled transistor T1 and resistor R42 to voltage source 41 (or some other suitable component such a digital to analog converter, to an output terminal of analog switch 49, to a first terminal of comparator 45, and to a first terminal of comparator 47. Note that the voltage source can be programmable having control signal applied thereto. The output terminals of comparator 45 and 47 are applied to decision logic unit 46. Comparator 45 has a first reference voltage Vref(1) to a second terminal thereof, while comparator 47 has a second reference voltage Vref(2) applied to a second terminal thereof. Transistor T1 has an ENABLE signal applied thereto. The selected sense line provides a voltage drop that determines the voltage level applied to the second input terminals of comparators 45 and 47. The output signals from the comparators 45 and 47 indicate whether the sense line is terminated with a high impedance or with a low impedance. Because the plurality of target processor systems can be used with the emulation system, the parameters of the voltage V41, the reference voltages Vref(1) and Vref(2), and the resistor R41 are fixed, the output signals of the comparators 45 and 47 may not provide an accurate representation of the relative impedances of the two sense lines. In this event, an enable signal is applied to transistor T1 and control signals are applied to analog to digital converter 41. The control signals applied to the analog to digital converter 41 provide an appropriate voltage so that, with respect to Vref(1) and the Vref(2), appropriate high impedance and low impedance signals are generated at the output terminals of comparators 45 and 47. The relative values of the resistors R41 and R42 are selected so that when the enable signal is applied to transistor T1, the voltage level at the output of the digital to analog converter 41 will dominate the signal level generated by the voltage V41.

Referring once again to FIG. 4, the output of the analog switch 49 is coupled to the output terminal of switch unit 31. The analog switch 49 has the /TRST signal applied to an input terminal thereof and an enable signal applied thereto. When the decision logic has identified the appropriate sense line, the decision logic unit applies control signals to the switch unit 31 to insure that the appropriate sense line is coupled to the output terminal of switch unit 31. The analog switch 49 is enabled (i.e., by the decision logic) and signals can be exchanged over the selected sense line. When signals are to be exchanged over the non-selected sense line, the decision logic applies appropriate control signals to the switch unit 48 so that signals can be exchanged over the non-selected sense line.

Referring next to FIG. 5, a second embodiment for identifying the characteristics of the sense lines is illustrated. In this embodiment, the control unit 32 selects a current sense line. The sense line is coupled to an output terminal of the switch unit 31 by means of control signals applied to switch unit 31. The output terminal of the switch unit is coupled through resistor R51 to voltage V51, is coupled to an input terminal of analog to digital converter 51 and is coupled through resistor R52 to transistor T52. The output signal of the analog to digital converter 51 is applied to decision logic 56. The decision logic determines whether the output signal from the analog to digital converter 51 indicates whether the selected sense is a high impedance or a low impedance. When the output from the analog to digital converter does not indicate the selected sense line, then the other sense line is coupled to the output terminal of the switch unit 31. The decision logic unit 56 determines whether the current sense line is the selected sense line. Or, the decision logic can test the characteristics of both sense lines and then determine which is the selected sense line. The decision logic unit 56, having determined which sense line is the selected sense line, couples the selected sense line to the output terminal of the switch unit 31. An enable signal is then applied to transistor T52 permitting the /TRST signal to be applied to the selected sense line. When the non-selected sense line is to be used for the transmission of signals, then control signals are applied to the switch unit 58 whereby signals can be exchanged between the target processor and the emulation unit over the non-selected sense line.

2. Operation of the Preferred Embodiment

The purpose of the present invention is to identify which of the sense lines can be used for a signal and still provide connector orientation. The sense line is coupled to one of two terminals on the connectors of the emulator cable. The two connectors are located symmetrically with respect to 180° rotation. This symmetry eliminates the need for a key pin, but provides ambiguity with respect to the coupling by the emulator cable to terminals on the target processor and the emulator unit. The present invention permits the relative rotation of the emulation unit connectors to be determined. In particular, in the preferred embodiment, one terminal of the target processor is designated as the terminal to which the /TRST signal is applied. The /TRST terminal is always coupled to one of the two sense lines. The apparatus of the present invention, based on the characteristics of the sense lines, determines to which of the two sense lines the /TRST terminal is coupled. The appropriate sense line can then be coupled to the /TRST signal. In this manner, one of the sense lines can be used to carry a non-optional signal (in the JTAG format).

As will be clear, a protocol will be established with respect to the testing of the sense lines. For example, one of the sense lines can be tested for a predetermined characteristic. When the predetermined characteristic is not present, then the protocol may dictate that the untested sense line has the predetermined characteristic. Or, the protocol may require that the untested sense line be tested to insure that the predetermined characteristic is present. Once the sense line having the predetermined characteristic is identified, then the related signal can be applied to that sense line. And, if appropriate, another signal terminal can be applied to the sense line not having the predetermined characteristic.

Furthermore, it will be clear to those skilled in art that determination of orientation of the connector can be used to control switches, the switches determining the origin/destination of signals exchanged over the connector. Thus, once the orientation of the connector is determined, the function of each particular connector conductor can be controlled.

This technique can be applied to target/emulator connectors having an arbitrary configuration and an arbitrary number of connecting cables. The sensing procedure can be applied to one or to a plurality of signals. Other test signals, such as the /TRST signal can be applied to any pin that is being monitored. For example, if 4 pins can be sensing the orientation, these four pins can be assigned a preselected functionality based on the orientation.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. Sensing apparatus to determine the relative orientation of two cable connectors, the connector cable coupling a target device and a test device, the two cable connectors coupled to two sense lines, the two sense lines coupled to two equivalently-placed connector terminals of each cable connector, the two related connector terminals having 180° rotation symmetry for each cable connector; the target and test device having device connectors for coupling to the cable connectors, a first sense line being coupled to a preestablished impedance, the apparatus comprising:
a switch having a first and a second conductor applied thereto, the switch applying a selected sense line to the emulation unit in response to first control signals; and
an emulation unit, the emulation unit including:
a logic unit for generating control signals; and
a characteristic determination unit, the characteristic determination unit determining a characteristic of the selected sense line, applying the first control signal to the switch when the first sense line has a predetermined characteristic.

2. The apparatus as recited in claim 1 wherein, when the first sense line does not have the predetermined characteristic, the logic unit generates second control signals to the switch, the switch in response to the second set of control signals causing the second sense line to be applied to the emulator unit, the characteristic determination unit determining the second sense line characteristic.

3. The apparatus as recited in claim 2 wherein the sense line having the predetermined characteristic is coupled to the /TRST signal terminal of the target processor.

4. The apparatus as recited in claim 2 further comprising a switch coupled to the two sense lines, the switch in response to control signals coupling a preselected terminal of the emulation unit to the sense line not having the predetermined characteristic.

5. The apparatus as recited in claim 1 wherein determination of the connector orientation can control the signals assigned to the individual cable conductors.

6. The method of exchanging data signals between a target processor and an emulation unit, the method comprising:
in a cable electrically coupling the target processor and the emulation unit, designating two associated terminals of each cable connector as sense lines, the sense lines having a 180° rotational symmetry for each connector;
determining the characteristics for at least one sense line; and
when a sense line is determined to have a preselected characteristic, transmitting preselected signals to the target processor over the sense line having the predetermined characteristic.

7. The method as recited in claim 6 wherein the preselected characteristic is an impedance range.

8. The method as recited in claim 6 wherein the preselected characteristic is a voltage level.

9. The method as recited in claim 6 further comprising applying a controllable voltage level to the one sense line.

10. The method as recited in claim 6 further comprising controlling the signal of each cable conduction in response to determination of characteristics of a sense line.

11. An apparatus in an emulator unit for controlling the transfer of signals between the emulation unit and a target processor over a cable, the cable including two sense lines, the apparatus comprising:
a switch coupled to the sense lines, the switch responsive to first control signals for selecting a selected sense line; and
characteristic determination unit in the emulation unit for determining a characteristic of the selected sense line.

12. The apparatus as recited in claim 11 further comprising a switch unit responsive to second control signals from the characteristic determination unit for coupling a sense unit having a predetermined characteristic to a first terminal.

13. The apparatus as recited in claim 12 wherein the first terminal has the /TRST JTAG signal applied thereto.

14. The apparatus as recited in claim 11 wherein the characteristic determination unit determines an impedance range.

15. The apparatus as recited in claim 13 wherein the characteristic determination unit includes a controllable voltage unit.

16. The apparatus as recited in claim 11 wherein the characteristic determination unit determines a voltage level.

17. The apparatus as recited in claim 11 wherein the characteristic determination controls the signals assigned to each conductor of the cable.
